(19) United States
(12) Patent Application Publication
(10) Pub. No.: US 2023/0282581 A1
(43) Pub. Date: Sep. 7, 2023

(54) LATERAL SEMICONDUCTOR DEVICE COMPRISING UNIT CELLS WITH HEXAGON CONTOURS

(71) Applicant: HUAWEI TECHNOLOGIES CO., LTD., Shenzhen (CN)

(72) Inventor: Samir Mouhoubi, Nuremberg (DE)

(73) Assignee: HUAWEI TECHNOLOGIES CO., LTD., Shenzhen (CN)

(21) Appl. No.: 18/316,165

(22) Filed: May 11, 2023

Related U.S. Application Data
(63) Continuation of application No. PCT/EP2020/081792, filed on Nov. 11, 2020.

(51) Int. Cl. H01L 23/528; H01L 27/088

(52) U.S. Cl. CPC H01L 23/5286; H01L 27/088

(57) ABSTRACT

A semiconductor device includes a die layer comprising a main surface. A plurality of first terminals are mounted on the main surface of the die layer, the first terminals forming a grid of unit cells with hexagon contours arranged side-by-side across the main surface of the die layer. A plurality of second terminals are mounted on the main surface of the die layer, each second terminal forming a hexagon contour arranged within a unit cell of a respective first terminal. A plurality of third terminals is mounted on the main surface of the die layer, each third terminal formed as a hexagon and arranged within the hexagon contour of a respective second terminal. At least two metallization layers are arranged over the plurality of first, second and third terminals and are configured to receive electrical currents from the plurality of first, second and third terminals.

### CROSS-REFERENCE TO RELATED APPLICATIONS

This application is a continuation of International Application No. PCT/EP2020/081792 filed on Nov. 11, 2020, the disclosure of which is hereby incorporated by reference in its entirety.

### TECHNICAL FIELD

The present disclosure relates to a semiconductor device, in particular a hexagonal lateral semiconductor device. The disclosure particularly relates to a hexagonal lateral GaN-eHEMT (Gallium-Nitride enhancement mode High Electron Mobility Transistor) with a full topside current extraction. The semiconductor device can be used as a power semiconductor device in power supply, automotive, LiDAR, servers, adaptors, etc.

### BACKGROUND

The simplest and widely used layout for Power Semiconductor devices is the “stripe” configuration as shown in FIG. 1; which enforces careful termination design. In pGaN based eHEMTs, this implies:
1) The pGaN stripe 12 (forming the gate terminal) needs to encapsulate the source contact 11 to avoid 2DEG (two-dimensional electron gas) formation at the stripe end (otherwise Drain 13—Source 11 short). This causes strong bending 14 of the pGaN stripe 12 leading to disturb the electric field (strong symmetry rupture) as shown in FIG. 1b. This induces an increase of leakage.
2) Electrically deactivate (isolate) 16 the stripe end 15 as shown in FIG. 1c: Widely adopted solution is N2 implantation of the AlGaN/GaN at the termination region (permanent material damage to delimit the Active region). This implant is performed through the pGaN layer, which damages the pGaN atomic structure and potentially creates leakage.

Both solutions above exhibit electrical weakness: potential leakage increase in both ON and OFF states leading to increased circuit consumption and degradation of gate over time (High Temperature Reverse Bias, HTRB, High Temperature Gate Bias, HTGB, Vth shift, etc.). Such design/layout specific issues were reported in ON-state (Namely Vth shift and HTGB weakness). An example of such Drain leakage increase linked to the degradation of pinch-off properties caused by the gate end design is shown in FIG. 2, where graph 21 shows the expected leakage of a normal transistor and graph 22 shows high drain to source leakage in the subthreshold regime (even at low Vds).

### SUMMARY

It is the object of this disclosure to provide a solution for the above described problems. Thus, it is an object of the disclosure to provide a semiconductor device with reduced Drain leakage.

This object is achieved by the features of the independent claims. Further implementation forms are apparent from the dependent claims, the description and the figures.

A basic idea of this disclosure is to eliminate the “stripe” structure of power semiconductor devices described above and to use a closed geometrical shape, i.e. a closed unit cell. Such a disruptive solution improves symmetry and gives maximum capability to fill in the “die” area (in general, the die has rectangular shape). From the three different shapes which were analyzed (see FIG. 3), the hexagonal shape is the optimal closed shape. To overcome the weakness of the gate end, the solution according to this disclosure is to change the stripe layout to a Hexagonal layout with a full topside current extraction. More details are given below.

The solution according to the disclosure solves the particular weakness of lateral pGaN HEMT structures linked to the combination of the pGaN gate concept with the standard stripe configuration. The Hexagonal unit cell concept eliminates the “pGaN” end region and restores symmetry. The main gain is to eliminate the parasitic leakages. The full topside current extraction allows to overcome the technological complexity and associated cost of backside contacting of a lateral device (trench etching, backside lithography, double-side wafer handling, etc.).

The structure is a GaN HEMT, i.e. a lateral power semiconductor device. The structure may be implemented as a pGaN-gate HEMT. It features a GaN HEMT with a gate in p-type GaN semiconductor to obtain E-Mode function (Enhanced mode that provides a normally off device). The p-type layer can be obtained by epitaxial growth of Mg-doped GaN material, but other technics are also possible. Despite we call the Gate in the examples shown hereinafter a “pGaN gate” because it contains p-type doping, this disclosure covers also other engineering examples of the gate such as for example alternate several layers of p-type-GaN, n-type-GaN or undoped-GaN layers. The structure features a closed cell layout with a hexagonal shape. It replaces the standard striped layout where the Gate, Drain and Source are parallel stripes ending close to the limit of the active area or extending beyond it. The hexagonal shape can feature a Source (or a Drain) in the center of the Hexagon. The corners of the hexagonal shapes (Source, Drain, Gate) can be rounded to decrease local electric field. The structure can be built on heteroepitaxial bulk (GaN-on-SOI, GaN on Sapphire, GaN-on SiC, etc.) or built on a GaN-on-GaN material. The pGaN gate can be a planar layer or a filling layer (for example in case of a regrowth of pGaN in a trench gate). The extraction of Drain, Source and Gate currents is done at the topside of the wafer.

According to a first example (shown below in FIGS. 4 and 5), the current extraction can be realized by using one metal level to extract the current of each terminal (Source, Drain and Gate). Another metal level can be used to route the currents towards the bond pads (or outside the device).

According to a second example (shown below in FIGS. 6 and 7), the current extraction can be done by sharing the routing towards the outside between the metal planes (levels). For example, source is routed in Metal1, Drain and Gate are routed in Metal2.

According to a third example (shown below in FIGS. 8 and 9), the current can be extracted using dedicated metal levels for each terminal. For example, gate is routed with metal1, source with Metal2 and drain with Metal3.

The following benefits can be realized by such design: Decreased device leakage (circuit consumption) in OFF-state; Improved device lifetime under HTRB and HTGB; Elimination of the Vth shifts linked to the leakage; Solving the electromigration constraints typical of lateral structures (coupled with stripes); Reduction of die size and decrease of cost; Improved power density; Reduction of thermal and electrical non-homogeneities across the die; Solving the issue of electrical field peaks at gate ends; Compact design (i.e. cost reduction); Overcoming the need of backside wafer handling and etching technologies; Reduction of technology complexity and cost.

In order to describe the invention in detail, the following terms, abbreviations and notations will be used:
HEMT High Electron Mobility Transistor
GaN Gallium-Nitride
eHEMT enhancement mode High Electron Mobility Transistor
HTRB High Temperature Reverse Bias
HTGB High Temperature Gate Bias

A HEMT is a high-electron-mobility transistor (HEMT), also known as heterostructure FET (HFET) or modulation-doped FET (MODFET), is a field-effect transistor incorporating a junction between two materials with different band gaps (i.e., a heterojunction) as the channel instead of a doped region (as is generally the case for a MOSFET). A commonly used material combination is GaAs with AlGaAs, though there is wide variation, dependent on the application of the device.

According to a first aspect, the disclosure relates to a semiconductor device, comprising: a die layer comprising a main surface; a plurality of first terminals mounted on the main surface of the die layer, wherein the first terminals form a grid of unit cells with hexagon contours arranged side-by-side across the main surface of the die layer; a plurality of second terminals mounted on the main surface of the die layer, wherein each second terminal forms a hexagon contour arranged within a unit cell of a respective first terminal, wherein there is a gap between the second terminal and the first terminal; a plurality of third terminals mounted on the main surface of the die layer, wherein each third terminal is formed as a hexagon and arranged within the hexagon contour of a respective second terminal, wherein there is a second gap between the third terminal and the second terminal; and at least two metallization layers arranged over the plurality of first, second and third terminals, configured to receive electrical currents from the plurality of first, second and third terminals.

A gap refers to various openings, vacant spaces, lacks or pauses. A gap designates a break or hole between two objects such as the above terminals. A gap between two terminals means that the two terminals do not touch each other.

The gap between the two terminals may be filled with isolation material to avoid electrical connection between the two terminals.

In one example, first terminals may be source terminals, second terminals may be gate terminals and third terminals may be drain terminals. In another example, first terminals may be gate terminals, second terminals may be drain terminals and third terminals may be source terminals. Any other assignment between the terminals may be used as well.

The first terminal and the third terminals are not obligatory physical bodies but just areas that are called Source and Drain.

These terminals may represent cavities in the AlGaN layer and not necessarily bodies on top of it. That means, first terminals and third terminals may be laying on top of the main surface 111, or slightly below it, as exemplarily shown in FIG. 10.

First terminals and third terminals are contacts that may lay on top of the main surface or below it (in this case, the terminals are obtained by removing or etching through the die until a thickness Tcontact. Tcontact may be comprised between 0 nm from the main surface and a depth superior to the AlGaN thickness).

Such a semiconductor device according to the first aspect provides a solution for the particular weakness of lateral pGaN HEMT structures linked to the combination of the pGaN gate concept with the standard stripe configuration. The Hexagonal unit cell structure of the semiconductor device eliminates the “pGaN” end region and restores symmetry. Thus, parasitic leakages can be eliminated. The full topside current extraction of the semiconductor device allows to overcome the technological complexity and associated cost of backside contacting of a lateral device, e.g. by using trench etching, backside lithography, double-side wafer handling, etc.

In an exemplary implementation of the semiconductor device (referred hereinafter as Example 1), a first metallization layer M1 comprises a first portion, a second portion and a third portion which are separated from each other, wherein the first portion of the first metallization layer M1 is covering at least parts of each first terminal to receive electrical currents from the plurality of first terminals, wherein the second portion of the first metallization layer M1 is covering at least parts of each second terminal to receive electrical currents from the plurality of second terminals, wherein the third portion of the first metallization layer M1 is covering at least parts of each of third terminal to receive electrical currents from the plurality of third terminals.

Such a semiconductor device according to Example 1 provides the advantages of decreased device leakage in OFF-state, improved device lifetime under HTRB and HTGB, elimination of the Vth shifts linked to the leakage, reduction of die size and decrease of cost. Further advantages are improved power density, reduction of thermal and electrical non-homogeneities across the die, reduced electrical field peaks at gate ends. There is no need for backside wafer handling and etching technologies.

In an exemplary implementation of the semiconductor device (that may also belong to Example 1), a second metallization layer M2 is arranged over the first metallization layer M1, the second metallization layer M2 comprising a first portion, a second portion and a third portion which are separated from each other, wherein the first portion of the first metallization layer M1 is connected to the first portion of the second metallization layer M2 to route the extracted currents from the plurality of first terminals to another entity, wherein the second portion of the first metallization layer is connected to the second portion of the second metallization layer M2 to route the extracted currents from the plurality of second terminals to another entity, wherein the third portion of the first metallization layer M1 is connected to the third portion of the second metallization layer M2 to route the extracted currents from the plurality of third terminals to another entity.

In an exemplary implementation of the semiconductor device (that may also belong to Example 1), the first portion of the second metallization layer M2 is formed in a wavy shape covering parts of the hexagon contours of the plurality of first terminals, wherein the second portion of the second metallization layer M2 is formed in a wavy shape covering parts of the hexagon contours of the plurality of second terminals, wherein the third portion of the second metallization layer M2 is formed in a wavy shape covering the hexagons of the plurality of third terminals.

In an exemplary implementation of the semiconductor device (that may also belong to Example 1), an isolation layer is arranged between the first metallization layer M1 and the second metallization layer M2, wherein the connection between the first portion of the first metallization layer M1 and the first portion of the second metallization layer M2, the connection between the second portion of the first metallization layer M1 and the second portion of the second metallization layer M2, and the connection between the third portion of the first metallization layer M1 and the third portion of the second metallization layer M2 are formed by vias through the isolation layer.

In an exemplary implementation of the semiconductor device (referred hereinafter as Example 2), a first metallization layer M1 comprises a first portion and a second portion which are separated from each other, wherein the first portion of the first metallization layer M1 is covering at least parts of the plurality of first terminals to receive electrical currents from the first terminals, wherein the second portion of the first metallization layer M1 is covering at least parts of the plurality of second terminals to receive electrical currents from the second terminals.

Such a semiconductor device according to Example 2 provides the same advantages as described for the semiconductor device of Example 1, namely decreased device leakage in OFF-state, improved device lifetime under HTRB and HTGB, elimination of the Vth shifts linked to the leakage, reduction of die size and decrease of cost. Further advantages are improved power density, reduction of thermal and electrical non-homogeneities across the die, reduced electrical field peaks at gate ends. There is no need for backside wafer handling and etching technologies.

In an exemplary implementation of the semiconductor device (that may also belong to Example 2), a second metallization layer M2 is arranged over the first metallization layer M1, the second metallization layer M2 comprising a first portion and a second portion which are separated from each other, wherein the first portion of the second metallization layer M2 is covering at least parts of the plurality of third terminals to receive electrical currents from the third terminals.

In an exemplary implementation of the semiconductor device (that may also belong to Example 2), the first portion of the second metallization layer M2 is configured to route currents from the third terminals to another entity, wherein the first portion of the first metallization layer (M1) is configured to route currents from first terminals to another entity, and wherein the second portion of the second metallization layer M2 is connected to the second portion of the first metallization layer M1 to route currents from the second terminals to another entity.

In an exemplary implementation of the semiconductor device (that may also belong to Example 2), an isolation layer is arranged between the first metallization layer (M1) and the second metallization layer M2, wherein the connection between the second portion of the second metallization layer M2 and the second portion of the first metallization layer M1 is formed by a via through the isolation layer.

In an exemplary implementation of the semiconductor device (referred hereinafter as Example 3), a first metallization layer M1 is covering at least parts of the first terminals to receive electrical currents from the first terminals and route the currents from the first terminals to another entity, wherein a second metallization layer M2 is covering at least parts of the second terminals to receive electrical currents from the second terminals and route the currents from the second terminals to another entity, wherein a third metallization layer M3 is covering at least parts of the third terminals to receive electrical currents from the third terminals and route the currents from the third terminals to another entity.

Such a semiconductor device according to Example 3 provides the same advantages as described for the semiconductor device of Example 1, namely decreased device leakage in OFF-state, improved device lifetime under HTRB and HTGB, elimination of the Vth shifts linked to the leakage, reduction of die size and decrease of cost. Further advantages are improved power density, reduction of thermal and electrical non-homogeneities across the die, reduced electrical field peaks at gate ends. There is no need for backside wafer handling and etching technologies.

In an exemplary implementation of the semiconductor device (that may also belong to Example 3), the second metallization layer M2 is arranged over the first metallization layer M1, and wherein the third metallization layer M3 is arranged over the second metallization layer M2.

In an exemplary implementation of the semiconductor device (that may also belong to Example 3), the third metallization layer M3 is fully covering the main surface of the die layer.

In an exemplary implementation of the semiconductor device (that may also belong to Example 3), the third terminals covered at least partially by the third metallization layer M3 are drain terminals, and wherein the first terminals and the second terminals are source terminals or gate terminals, respectively.

When going from M2 or M3 directly to the first, second or third terminals, this can be done directly (as shown in FIG. 9, for example) or through via's or plugs through the isolation layers (as shown in FIG. 11, for example).

In an exemplary implementation of the semiconductor device, at least one of the hexagon contours of the plurality of first terminals, the hexagon contours of the plurality of second terminals or the hexagons of the plurality of third terminals have rounded corners or cut corners.

FIG. 12 shows examples for a hexagon with standard corners 601, a hexagon with cut corners 602 and a hexagon with rounded corners 603.

In an exemplary implementation of the semiconductor device, the semiconductor device comprises a lateral power semiconductor device comprising a GaN High Electron Mobility Transistor, HEMT, device.

A HEMT is a high-electron-mobility transistor (HEMT), also known as heterostructure FET (HFET) or modulation-doped FET (MODFET), is a field-effect transistor incorporating a junction between two materials with different band gaps (i.e. a heterojunction) as the channel instead of a doped region (as is generally the case for a MOSFET). A commonly used material combination is GaAs with AlGaAs, though there is wide variation, dependent on the application of the device.

In an exemplary implementation of the semiconductor device, the die layer comprises a GaN layer and an AlGaN layer above the GaN layer, wherein the main surface is formed on top of the AlGaN layer.

In an exemplary implementation of the semiconductor device, the plurality of first terminals, the plurality of second terminals and the plurality of third terminals are formed on one level on top of the AlGaN layer; or at least one of the plurality of first terminals, the plurality of second terminals and the plurality of third terminals is extending into the AlGaN layer; or at least one of the plurality of first terminals, the plurality of second terminals and the plurality of third terminals is extending into the GaN layer.

In an exemplary implementation of the semiconductor device, the semiconductor device comprises a GaN HEMT comprising a gate in at least partially p-type GaN semiconductor to obtain an enhanced mode that provides a normally off device.

The gate can be fully or partially p-type. This means, the gate can be designed in such a way that it includes a plurality of p-type, n-type or undoped-type GaN. For example, the gate can include an intermixture of p-type, n-type, or undoped GaN layers.

The p-type layer(s), as well as the n-type layer(s), can be obtained by epitaxial growth of Mg-doped GaN material. Other techniques are also possible.

In an exemplary implementation of the semiconductor device, the GaN layer is built on heteroepitaxial bulk, in particular GaN-on-SOI, GaN on Sapphire or GaN-on SiC, or built on GaN-on-GaN material.

In an exemplary implementation of the semiconductor device, the plurality of second terminals comprises a pGaN gate formed as a planar layer or as a filling layer, in particular in case of a regrowth of pGaN in a trench gate.

In an exemplary implementation of the semiconductor device, the at least two metallization layers M1, M2 are configured to route the electrical currents to another entity.

### BRIEF DESCRIPTION OF THE DRAWINGS

Further embodiments will be described with respect to the following figures, in which:

FIG. 1a shows a standard stripe layout configuration 10a with gate-end surrounding source stripe and embedded in Isolation;

FIG. 1b shows a zoom 10b of the layout configuration 10a illustrating a single source finger (stripe);

FIG. 1c shows a zoom 10c of another layout configuration illustrating a single source finger (stripe), where gate is not surrounding source;

FIG. 2 shows an exemplary transfer characteristic 20 of a pGaN HEMT in a standard stripe configuration;

FIG. 3a shows an example of a circular shape closed cell design 30a;

FIG. 3b shows an example of a hexagonal shape closed cell design 30b according to the disclosure;

FIG. 3c shows an example of a triangular shape closed cell design 30c;

FIG. 4 shows a schematic diagram illustrating a top view on a Hexagonal lateral HEMT 100 according to a first example (referred to as Example 1 hereinafter) according to the disclosure;

FIG. 5 shows a schematic diagram illustrating a sectional view on the Hexagonal lateral HEMT 100 according to the first example according to the disclosure;

FIG. 6 shows a schematic diagram illustrating a top view on a Hexagonal lateral HEMT 200 according to a second example (referred to as Example 2 hereinafter) according to the disclosure;

FIG. 7 shows a schematic diagram illustrating a sectional view on the Hexagonal lateral HEMT 200 according to the second example according to the disclosure;

FIG. 8 shows a schematic diagram illustrating a top view on a Hexagonal lateral HEMT 300 according to a third example (referred to as Example 3 hereinafter) according to the disclosure;

FIG. 9 shows a schematic diagram illustrating a sectional view on the Hexagonal lateral HEMT 300 according to the third example according to the disclosure;

FIG. 10 shows a schematic diagram illustrating a sectional view on a Hexagonal lateral HEMT 400 according to another implementation of the first example according to the disclosure;

FIG. 11 shows a schematic diagram illustrating a sectional view on a Hexagonal lateral HEMT 500 according to another implementation of the third example according to the disclosure;

FIG. 12a shows a schematic diagram illustrating a hexagonal shape design 601 of a Hexagonal lateral HEMT with standard corners according to the disclosure;

FIG. 12b shows a schematic diagram illustrating a hexagonal shape design 602 of a Hexagonal lateral HEMT with cut corners according to the disclosure; and

FIG. 12c shows a schematic diagram illustrating a hexagonal shape design 603 of a Hexagonal lateral HEMT with rounded corners according to the disclosure.

### DETAILED DESCRIPTION OF EMBODIMENTS

In the following detailed description, reference is made to the accompanying drawings, which form a part thereof, and in which is shown by way of illustration specific aspects in which the disclosure may be practiced. It is understood that other aspects may be utilized and structural or logical changes may be made without departing from the scope of the present disclosure. The following detailed description, therefore, is not to be taken in a limiting sense, and the scope of the present disclosure is defined by the appended claims.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

The semiconductor devices and systems described herein may be implemented in wireless communication schemes, in particular communication schemes compliant with 5G. The described semiconductor devices may be used to produce integrated circuits and/or power semiconductors and may be manufactured according to various technologies. For example, the semiconductor devices may be utilized in logic integrated circuits, analog integrated circuits, mixed signal integrated circuits, optical circuits, memory circuits and/or integrated passives.

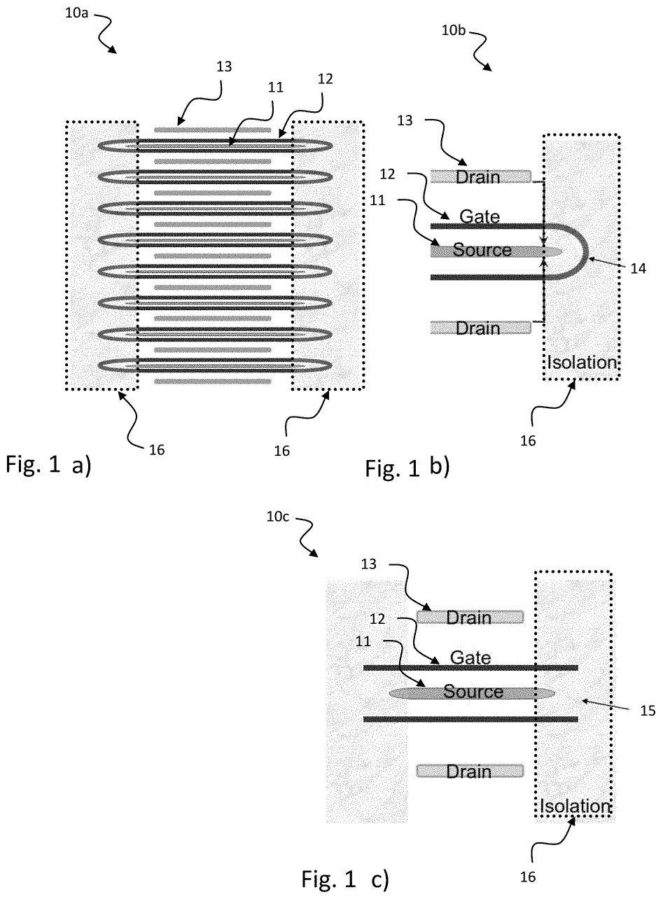

FIG. 1a shows a standard stripe layout configuration 10a for pGaN based eHEMTs with gate-end surrounding source stripe and embedded in Isolation and FIG. 1b shows a zoom 10b of this layout configuration 10a. The “stripe” configuration is the simplest and widely used layout for Power Semiconductor devices. In this configuration, the pGaN stripe 12 which forms the gate terminal encapsulates the source contact 11 to avoid 2DEG (two-dimensional electron gas) formation at the stripe end and thus to avoid Drain-Source short. This configuration, however, causes strong bending 14 of the pGaN stripe 12 leading to disturb the electric field (strong symmetry rupture) as shown in FIG. 1b. This induces an increase of leakage.

FIG. 1c shows a zoom 10c of another layout configuration illustrating a single source finger (stripe), where gate is not surrounding source. In this configuration, the stripe end 15 of the pGaN stripe 12 is electrically deactivated by isolation material 16. A widely adopted solution is N2 implantation of the AlGaN/GaN at the termination region 15 resulting in permanent material damage to delimit the active region. This implant is performed through the pGaN layer, which damages the pGaN atomic structure and potentially creates leakage.

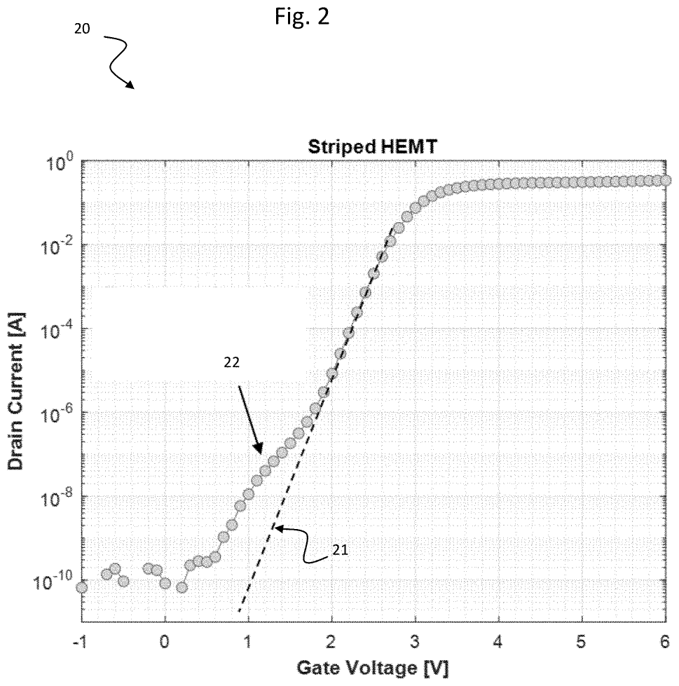

FIG. 2 shows an exemplary transfer characteristic 20 of a pGaN HEMT in a standard stripe configuration. Drain current in Amperes over gate voltage in Volts is shown. Graph 21 shows the expected leakage of a normal transistor and graph 22 shows high drain to source leakage in the subthreshold regime (even at low Vds). Such drain leakage increase is linked to the degradation of pinch-off properties caused by the gate end design as described above with respect to FIG. 1. Leakage is increased in both ON and OFF states leading to increased circuit consumption and degradation of gate over time with respect to HTRB and HTGB.

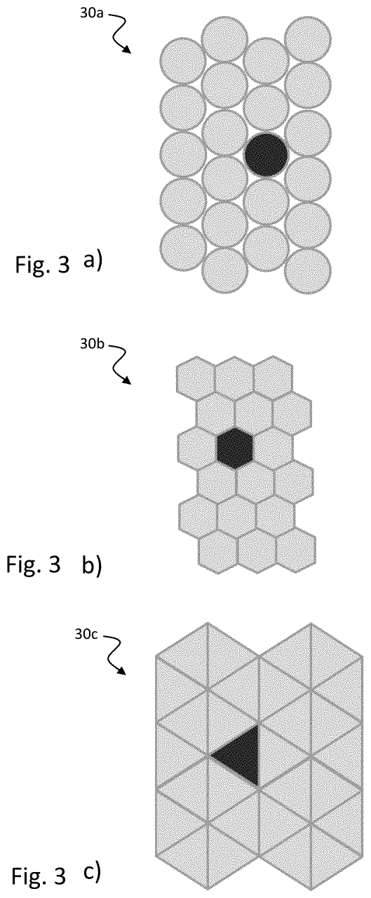

FIG. 3a shows an example of a circular shape closed cell design 30a. FIG. 3b shows an example of a hexagonal shape closed cell design 30b according to the disclosure. FIG. 3c shows an example of a triangular shape closed cell design 30c.

To eliminate the “stripe” structure of power semiconductor devices described above and to reduce the disadvantageous leakage effects, a closed geometrical shape design, i.e. a closed unit cell design is used. Such a design improves symmetry and gives superior capability to fill in the “die” area which generally has a rectangular shape. From the three different shapes shown in FIGS. 3a, 3b and 3c, the hexagonal shape closed cell design 30b has proved to be the optimal HEMT design. Therefore, semiconductor implementations described hereinafter are based on the hexagonal shape closed cell design 30b.

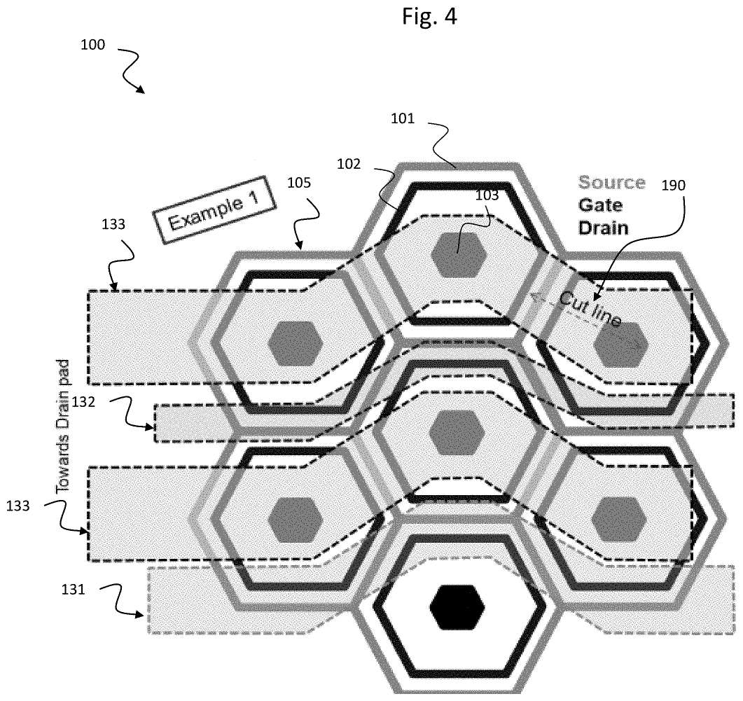

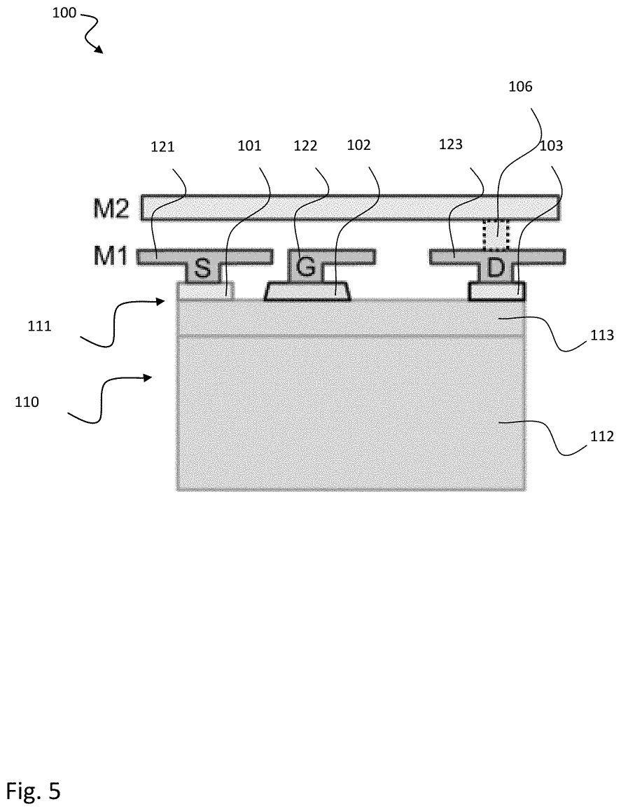

FIG. 4 shows a schematic diagram illustrating a top view on a Hexagonal lateral HEMT 100 according to a first example (referred to as Example 1 hereinafter) according to the disclosure and FIG. 5 shows a sectional view on the Hexagonal lateral HEMT 100. The cross section shown in FIG. 5 is extracted at the cutline 190 shown in FIG. 4.

This HEMT implementation according to Example 1 is characterized by a hexagonal layout and two main planes of metallization M1 and M2 at the topside. M1 is used to extract the current/voltage of each terminal (S, D, G) for each unit cell. All terminals share the M2 as Bus to route towards bond pads. The wavy shape of the Bus's allows extracting all terminals currents by VIAs. In Example 1, G and S are connected to M2 in the third dimension.

The semiconductor device 100 comprises a die layer 110 with a main surface 111. The semiconductor device 100 comprises a plurality of first terminals 101, S mounted on the main surface 111 of the die layer 110. The first terminals 101, S form a grid of unit cells 105 with hexagon contours arranged side-by-side across the main surface 111 of the die layer 110. The semiconductor device 100 comprises a plurality of second terminals 102, G mounted on the main surface 111 of the die layer 110. Each second terminal 102, G forms a hexagon contour arranged within a unit cell of a respective first terminal 101, S. There is a gap between the second terminal and the first terminal 101, S. The semiconductor device comprises a plurality of third terminals 103, D mounted on the main surface 111 of the die layer 110. Each third terminal 103, D is formed as a hexagon and arranged within the hexagon contour of a respective second terminal 102, G. There is a second gap between the third terminal 103, D and the second terminal 102, G. The semiconductor device 100 further comprises at least two metallization layers M1, M2 arranged over the plurality of first 101, S, second 102, G and third 103, D terminals, configured to receive electrical currents from the plurality of first, second and third terminals.

In the semiconductor device 100, a first metallization layer M1 comprises a first portion 121, a second portion 122 and a third portion 123 which are separated from each other. The first portion 121 of the first metallization layer M1 is covering at least parts of each first terminal 101, S to receive electrical currents from the plurality of first terminals 101, S. The second portion 122 of the first metallization layer M1 is covering at least parts of each second terminal 102, G to receive electrical currents from the plurality of second terminals 102, G. The third portion 123 of the first metallization layer M1 is covering at least parts of each of third terminal 103, D to receive electrical currents from the plurality of third terminals 103, D.

In the semiconductor device 100, a second metallization layer M2 is arranged over the first metallization layer M1. The second metallization layer M2 comprises a first portion 131, a second portion 132 and a third portion 133 which are separated from each other. The first portion 121 of the first metallization layer M1 is connected to the first portion 131 of the second metallization layer M2 to route the extracted currents from the plurality of first terminals 101, S to another entity. The second portion 122 of the first metallization layer M1 is connected to the second portion 132 of the second metallization layer M2 to route the extracted currents from the plurality of second terminals 102, G to another entity. The third portion 123 of the first metallization layer M1 is connected to the third portion 133 of the second metallization layer M2 to route the extracted currents from the plurality of third terminals 103, D to another entity.

In the semiconductor device 100, the first portion 131 of the second metallization layer M2 is formed in a wavy shape covering parts of the hexagon contours of the plurality of first terminals 101, S. The second portion 132 of the second metallization layer M2 is formed in a wavy shape covering parts of the hexagon contours of the plurality of second terminals 102, G. The third portion 133 of the second metallization layer M2 is also formed in a wavy shape covering the hexagons of the plurality of third terminals 103, D.

In the semiconductor device 100, an isolation layer is arranged between the first metallization layer M1 and the second metallization layer M2. The connection between the first portion 121 of the first metallization layer M1 and the first portion 131 of the second metallization layer M2, the connection between the second portion 122 of the first metallization layer M1 and the second portion 132 of the second metallization layer M2, and the connection between the third portion 123 of the first metallization layer M1 and the third portion 133 of the second metallization layer M2 are formed by vias 106 through the isolation layer.

At least one of the hexagon contours of the plurality of first terminals 101, S, the hexagon contours of the plurality of second terminals 102, G or the hexagons of the plurality of third terminals 103, D may have cut corners 602 or rounded corners 603 or standard corners 601.

The semiconductor device 100 may comprise a lateral power semiconductor device comprising a GaN High Electron Mobility Transistor, HEMT, device.

The die layer 110 may comprises a GaN layer 112 and an AlGaN layer 113 above the GaN layer 112. The main surface 111 may be formed on top of the AlGaN layer 113.

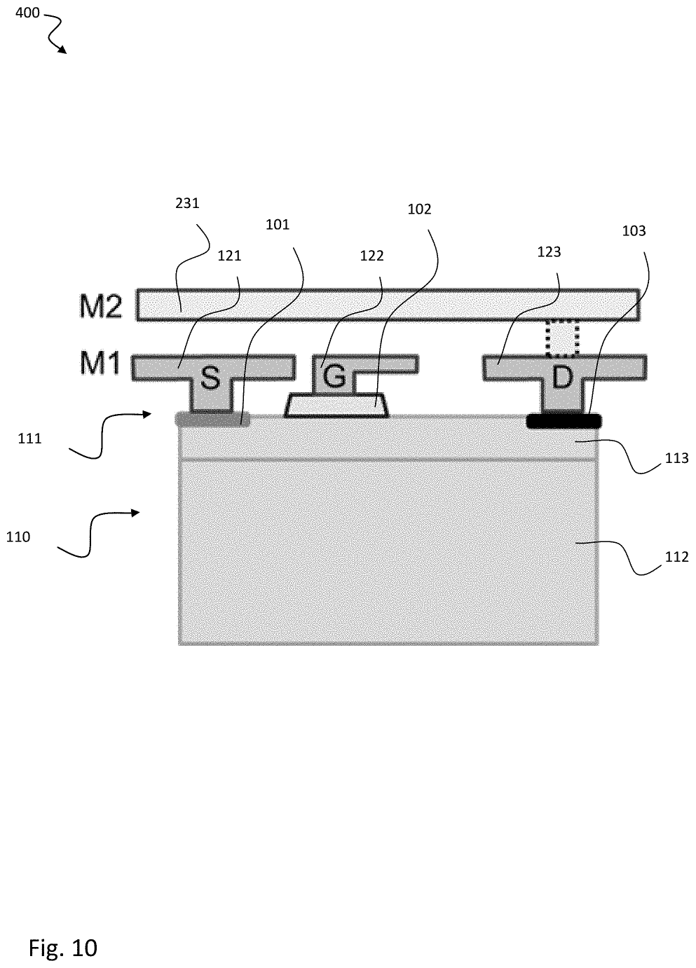

The plurality of first terminals 101, S, the plurality of second terminals 102, G and the plurality of third terminals 103, D may be formed on one level on top of the AlGaN layer 113. Alternatively, at least one of the plurality of first terminals 101, S, the plurality of second terminals 102, G and the plurality of third terminals (103, D) may be extending into the AlGaN layer 113, e.g. as shown in the configuration of FIG. 10. Alternatively, at least one of the plurality of first terminals 101, S, the plurality of second terminals 102, G and the plurality of third terminals 103, D may be extending into the GaN layer 113.

The semiconductor device 100 may comprise a GaN HEMT comprising a gate in p-type GaN semiconductor to obtain an enhanced mode that provides a normally off device.

The GaN layer 112 may be built on heteroepitaxial bulk, in particular GaN-on-SOI, GaN on Sapphire or GaN-on SiC, or built on GaN-on-GaN material.

The plurality of second terminals 102, G may comprise a pGaN gate formed as a planar layer or as a filling layer, in particular in case of a regrowth of pGaN in a trench gate.

The at least two metallization layers M1, M2 may be configured to route the electrical currents to another entity.

In one implementation, the die layer 110 may comprise a GaN un-doped layer arranged on buffer layers/transition layers/substrate. The first terminals 101 and the third terminals may be separated by an AlGaN layer which are all three formed on one level above the GaN un-doped layer. The second terminals 102 may be arranged on the AlGaN layer between the first terminals 101 and the third terminals 103 without touching these terminals.

In another implementation, the die layer 110 may comprise a Si substrate on which a transition layer is arranged on which a GaN buffer is formed on which an AlGaN barrier layer is formed. Metal electrodes are formed on this AlGaN barrier layer to implement the first and third terminals, e.g. Source and Drain. The second terminals, e.g. Gate, are arranged on the AlGaN barrier layer between the first and third terminals. The second terminals are separated from the first and third terminals by an isolation layer formed on the AlGaN barrier layer.

In another implementation, the die layer 110 may comprise a Si substrate on which an AlN nucleation layer is arranged on which a first, second and third AlGaN layer are formed. A GaN buffer layer is formed on the third AlGaN layer. The first and third terminals, e.g. source and drain are formed together with an AlN spacer layer separating both terminals on the GaN buffer layer. Between source and drain, a further AlGaN barrier layer is formed on the AlN spacer layer on which a GaN cap layer is formed. The second terminals, e.g. gate are formed on the GaN Cap layer separated by isolation layers from the first and third terminals.

In another implementation, the die layer 110 may comprise a GaN buffer on which the first and third terminal, e.g. source and drain are formed together with a barrier layer of AlGaN separating the first from the third terminals. On the barrier layer, a p-GaN pad is formed on which the second terminal, e.g. gate, is realized.

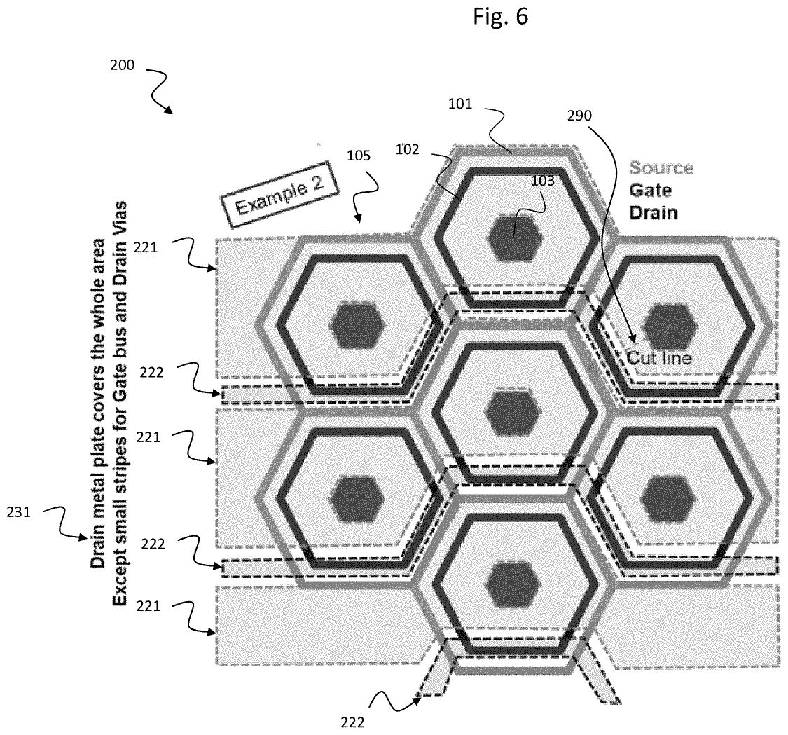

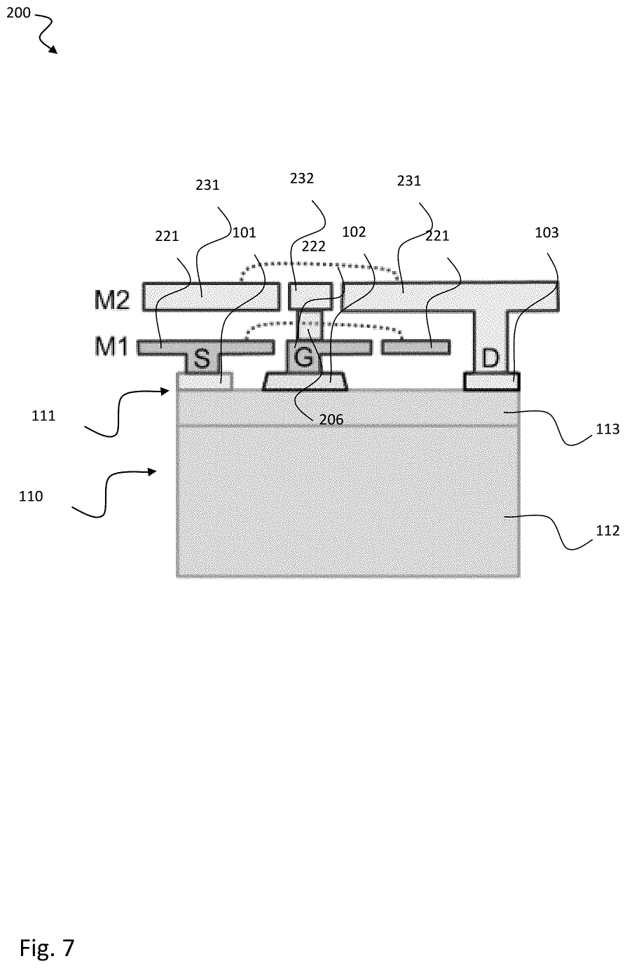

FIG. 6 shows a schematic diagram illustrating a top view on a Hexagonal lateral HEMT 200 according to a second example (referred to as Example 2 hereinafter) according to the disclosure and FIG. 7 shows a sectional view on the Hexagonal lateral HEMT 200. The cross section shown in FIG. 7 is extracted at the cutline 290 shown in FIG. 6.

In this HEMT implementation, a Hybrid interdigital metallization scheme is utilized. One terminal uses M1+VIA+M2 to route outside the unit cells. The two other terminals use each either M1 or M2. This implementation is a good compromise between electromigration and cost effectiveness.

In this Example 2, drain bus area is equal to source bus area; source bus area is at M1 level; drain bus is at M2 level; at both, M1 and M2, there is a small stripe of gate bus with inter-metal VIAs.

Drain metal plate covers the whole area except for small stripes for gate bus and drain vias.

In Example 2, S is routed in plane 1 and D and G in plane 2.

The principal structure of the semiconductor device 200 is similar to the semiconductor device 100 described above with respect to FIGS. 4 and 5. The semiconductor device 200 comprises a die layer 110 with a main surface 111. The semiconductor device 200 comprises a plurality of first terminals 101, S mounted on the main surface 111 of the die layer 110. The first terminals 101, S form a grid of unit cells 105 with hexagon contours arranged side-by-side across the main surface 111 of the die layer 110. The semiconductor device 200 comprises a plurality of second terminals 102, G mounted on the main surface of the die layer 110. Each second terminal 102, G forms a hexagon contour arranged within a unit cell of a respective first terminal 101, S. There is a gap between the second terminal and the first terminal 101, S. The semiconductor device 200 comprises a plurality of third terminals 103, D mounted on the main surface 111 of the die layer 110. Each third terminal 103, D is formed as a hexagon and arranged within the hexagon contour of a respective second terminal 102, G. There is a second gap between the third terminal 103, D and the second terminal 102, G. The semiconductor device 200 further comprises at least two metallization layers M1, M2 arranged over the plurality of first 101, S, second 102, G and third 103, D terminals, configured to receive electrical currents from the plurality of first, second and third terminals.

A first metallization layer M1 comprises a first portion 221 and a second portion 222 which are separated from each other. The first portion 221 of the first metallization layer M1 is covering at least parts of the plurality of first terminals 101, S to receive electrical currents from the first terminals 101, S. The second portion 222 of the first metallization layer M1 is covering at least parts of the plurality of second terminals 102, G to receive electrical currents from the second terminals 102, G.

A second metallization layer M2 is arranged over the first metallization layer M1. The second metallization layer M2 comprises a first portion 231 and a second portion 232 which are separated from each other. The first portion 231 of the second metallization layer M2 is covering at least parts of the plurality of third terminals 103, D to receive electrical currents from the third terminals 103, D.

The first portion 231 of the second metallization layer M2 is configured to route currents from the third terminals D to another entity. The first portion 221 of the first metallization layer M1 is configured to route currents from first terminals 101, S to another entity. The second portion 232 of the second metallization layer M2 is connected to the second portion of the first metallization layer M1 to route currents from the second terminals 102, G to another entity.

An isolation layer is arranged between the first metallization layer M1 and the second metallization layer M2. The connection between the second portion 232 of the second metallization layer M2 and the second portion 222 of the first metallization layer M1 is formed by a via 206 through the isolation layer.

Similar to the semiconductor device 100, also in the semiconductor device 200, at least one of the hexagon contours of the plurality of first terminals 101, S, the hexagon contours of the plurality of second terminals 102, G or the hexagons of the plurality of third terminals 103, D may have cut corners 602 or rounded corners 603 or standard corners 601.

The semiconductor device 200 may comprise a lateral power semiconductor device comprising a GaN High Electron Mobility Transistor, HEMT, device.

As described above for the semiconductor device 100, also for the semiconductor device 200, the die layer 110 may comprises a GaN layer 112 and an AlGaN layer 113 above the GaN layer 112. The main surface 111 may be formed on top of the AlGaN layer 113.

The plurality of first terminals 101, S, the plurality of second terminals 102, G and the plurality of third terminals 103, D may be formed on one level on top of the AlGaN layer 113. Alternatively, at least one of the plurality of first terminals 101, S, the plurality of second terminals 102, G and the plurality of third terminals 103, D may be extending into the AlGaN layer 113, e.g. as shown in the configuration of FIG. 10. Alternatively, at least one of the plurality of first terminals 101, S, the plurality of second terminals 102, G and the plurality of third terminals 103, D may be extending into the GaN layer 113.

The semiconductor device 200 may comprise a GaN HEMT comprising a gate in p-type GaN semiconductor to obtain an enhanced mode that provides a normally off device.

The GaN layer 112 may be built on heteroepitaxial bulk, in particular GaN-on-SOI, GaN on Sapphire or GaN-on SiC, or built on GaN-on-GaN material.

The plurality of second terminals 102, G may comprise a pGaN gate formed as a planar layer or as a filling layer, in particular in case of a regrowth of pGaN in a trench gate.

The at least two metallization layers M1, M2 may be configured to route the electrical currents to another entity.

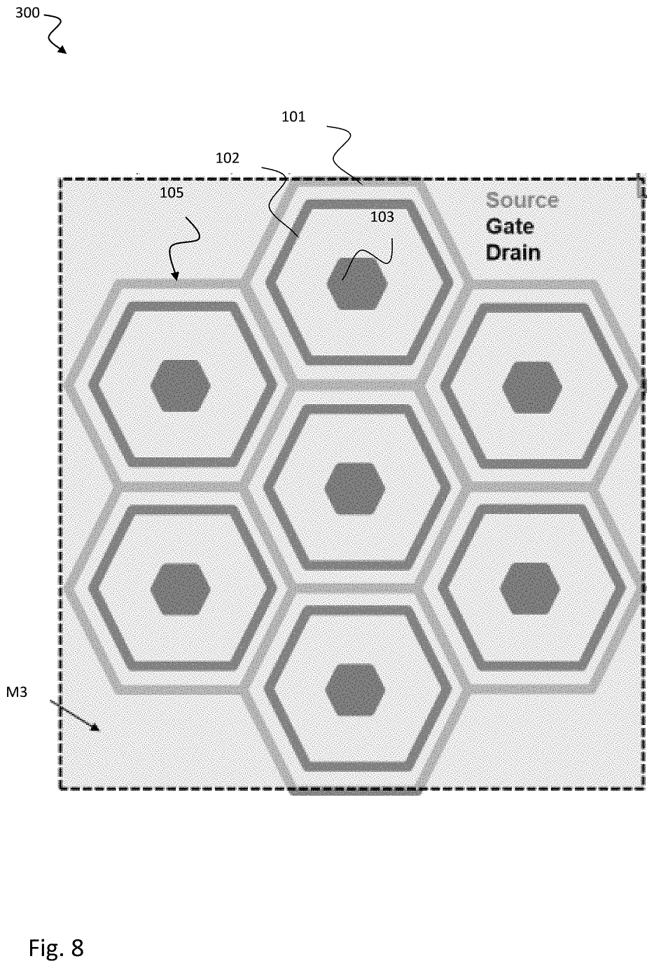

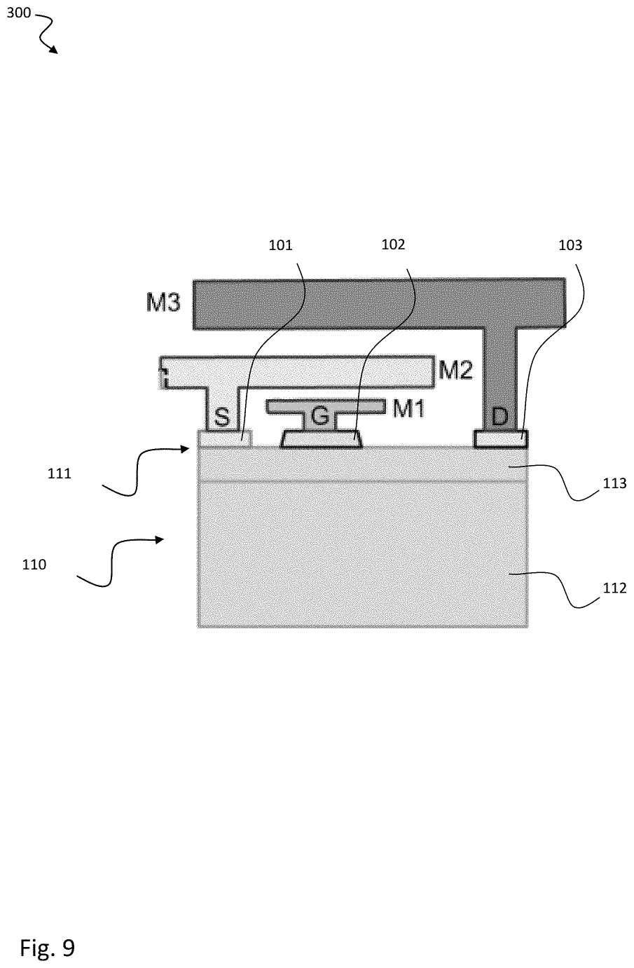

FIG. 8 shows a schematic diagram illustrating a top view on a Hexagonal lateral HEMT 300 according to a third example (referred to as Example 3 hereinafter) according to the disclosure and FIG. 9 shows a sectional view on the Hexagonal lateral HEMT 300.

In this HEMT implementation, a hexagonal layout and three main planes of metallization (at the topside) are utilized. In this case, every electrical terminal (D, S, G) has its own metal level. This is a slightly more expensive approach but provides the highest level of design freedom. In the implementation according to Example 3, each terminal uses its own metal level as a Bus. The best configuration is where D is routed at M3. S (or G) can be at M1 or M2.

The principal structure of the semiconductor device 300 is similar to the semiconductor device 100 described above with respect to FIGS. 4 and 5. The semiconductor device 300 comprises a die layer 110 with a main surface 111. The semiconductor device 300 comprises a plurality of first terminals 101, S mounted on the main surface 111 of the die layer 110. The first terminals 101, S form a grid of unit cells 105 with hexagon contours arranged side-by-side across the main surface 111 of the die layer 110. The semiconductor device 300 comprises a plurality of second terminals 102, G mounted on the main surface of the die layer 110. Each second terminal 102, G forms a hexagon contour arranged within a unit cell of a respective first terminal 101, S. There is a gap between the second terminal and the first terminal 101, S. The semiconductor device 300 comprises a plurality of third terminals 103, D mounted on the main surface 111 of the die layer 110. Each third terminal 103, D is formed as a hexagon and arranged within the hexagon contour of a respective second terminal 102, G. There is a second gap between the third terminal 103, D and the second terminal 102, G. The semiconductor device 300 further comprises at least two metallization layers M1, M2 arranged over the plurality of first 101, S, second 102, G and third 103, D terminals, configured to receive electrical currents from the plurality of first, second and third terminals.

A first metallization layer M1 is covering at least parts of the first terminals 101, S to receive electrical currents from the first terminals 101, S and route the currents from the first terminals 101, S to another entity. A second metallization layer M2 is covering at least parts of the second terminals 102, G to receive electrical currents from the second terminals 102, G and route the currents from the second terminals 102, G to another entity. A third metallization layer M3 is covering at least parts of the third terminals 103, D to receive electrical currents from the third terminals 103, D and route the currents from the third terminals 103, D to another entity.

The second metallization layer M2 is arranged over the first metallization layer M1. The third metallization layer M3 is arranged over the second metallization layer M2.

The third metallization layer M3 is fully covering the main surface 111 of the die layer 110.

The third terminals 103, D covered at least partially by the third metallization layer M3 are drain terminals. The first terminals 101, S and the second terminals 102, G are source terminals or gate terminals, respectively.

Similar to the semiconductor device 100, also in the semiconductor device 300, at least one of the hexagon contours of the plurality of first terminals 101, S, the hexagon contours of the plurality of second terminals 102, G or the hexagons of the plurality of third terminals 103, D may have cut corners 602 or rounded corners 603 or standard corners 601.

The semiconductor device 300 may comprise a lateral power semiconductor device comprising a GaN High Electron Mobility Transistor, HEMT, device.

As described above for the semiconductor device 100, also for the semiconductor device 300, the die layer 110 may comprises a GaN layer 112 and an AlGaN layer 113 above the GaN layer 112. The main surface 111 may be formed on top of the AlGaN layer 113.

The plurality of first terminals 101, S, the plurality of second terminals 102, G and the plurality of third terminals 103, D may be formed on one level on top of the AlGaN layer 113. Alternatively, at least one of the plurality of first terminals 101, S, the plurality of second terminals 102, G and the plurality of third terminals 103, D may be extending into the AlGaN layer 113, e.g. as shown in the configuration of FIG. 10. Alternatively, at least one of the plurality of first terminals 101, S, the plurality of second terminals 102, G and the plurality of third terminals 103, D may be extending into the GaN layer 113.

The semiconductor device 300 may comprise a GaN HEMT comprising a gate in p-type GaN semiconductor to obtain an enhanced mode that provides a normally off device.

The GaN layer 112 may be built on heteroepitaxial bulk, in particular GaN-on-SOI, GaN on Sapphire or GaN-on SiC, or built on GaN-on-GaN material.

The plurality of second terminals 102, G may comprise a pGaN gate formed as a planar layer or as a filling layer, in particular in case of a regrowth of pGaN in a trench gate.

The at least two metallization layers M1, M2 may be configured to route the electrical currents to another entity.

FIG. 10 shows a schematic diagram illustrating a sectional view on a Hexagonal lateral HEMT 400 according to another implementation of the first example according to the disclosure.

The structure of the semiconductor device 400 shown in FIG. 10 corresponds to the structure of the semiconductor device 100 shown in FIGS. 4 and 5. The difference is the design of the first 101 and third 103 terminals.

The first terminals 101 and the third terminals 103 are not obligatory physical bodies but just areas that are called Source and Drain, for example.

These terminals may represent cavities in the AlGaN layer 113 and not necessarily bodies on top of it. That means, first terminals 101 and third terminals 103 may be laying on top of the main surface 111, or slightly below it, as exemplarily shown in FIG. 10.

First terminals 101 and third terminals 103 are contacts that may lay on top of the main surface or below it. The First terminals 101 and third terminals 103 may be obtained by removing or etching through the die 110 until a thickness Tcontact, for example. Tcontact may be comprised between 0 nm from the main surface 111 and a depth superior to the AlGaN thickness.

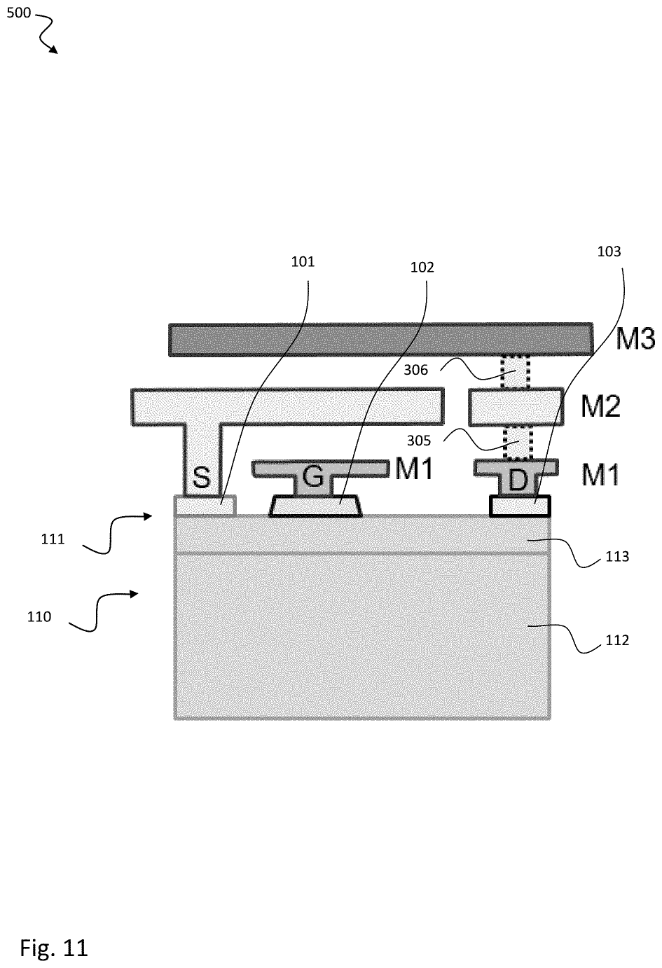

FIG. 11 shows a schematic diagram illustrating a sectional view on a Hexagonal lateral HEMT 500 according to another implementation of the third example according to the disclosure.

The structure of the semiconductor device 500 shown in FIG. 11 corresponds to the structure of the semiconductor device 300 shown in FIGS. 8 and 9. The difference is the design of the third terminals 103 that are routed by vias 305, 306 through the first metallization layer M1 and the second metallization layer M2.

This difference can be applied to any terminal 101, 102, 103. That means, connection to any terminal (Drain, Gate or Source) to the higher levels of metallization can be realized directly (as shown in FIG. 9 for Drain) or through vias between M1, M2 and M3 as exemplarily shown in FIG. 11 for Drain.

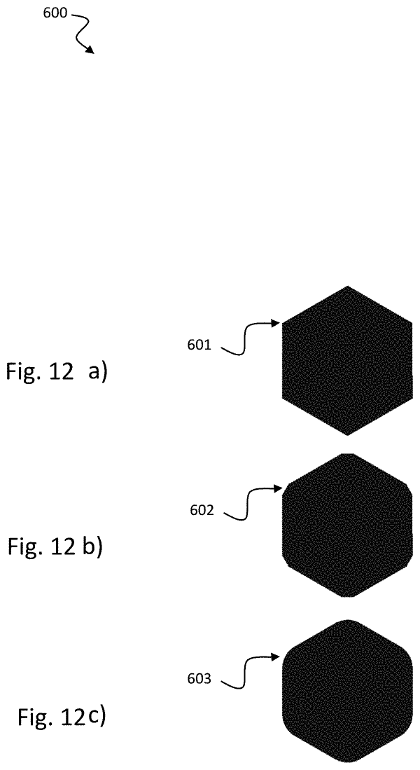

FIG. 12a shows a schematic diagram illustrating a hexagonal shape design 601 of a Hexagonal lateral HEMT with standard corners 601 according to the disclosure.

As described above, at least one of the hexagon contours of the plurality of first terminals 101, S, the hexagon contours of the plurality of second terminals 102, G or the hexagons of the plurality of third terminals 103, D may have standard corners 601.

FIG. 12b shows a schematic diagram illustrating a hexagonal shape design 602 of a Hexagonal lateral HEMT with cut corners 602 according to the disclosure.

As described above, at least one of the hexagon contours of the plurality of first terminals 101, S, the hexagon contours of the plurality of second terminals 102, G or the hexagons of the plurality of third terminals 103, D may have cut corners 602.

FIG. 12c shows a schematic diagram illustrating a hexagonal shape design 603 of a Hexagonal lateral HEMT with rounded corners 603 according to the disclosure.

As described above, at least one of the hexagon contours of the plurality of first terminals 101, S, the hexagon contours of the plurality of second terminals 102, G or the hexagons of the plurality of third terminals 103, D may have rounded corners 603.

While a particular feature or aspect of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the present disclosure. This application is intended to cover any adaptations or variations of the specific aspects discussed herein.

Although the elements in the following claims are recited in a particular sequence with corresponding labeling, unless the claim recitations otherwise imply a particular sequence for implementing some or all of those elements, those elements are not necessarily intended to be limited to being implemented in that particular sequence.

Many alternatives, modifications, and variations will be apparent to those skilled in the art in light of the above teachings. Of course, those skilled in the art readily recognize that there are numerous applications of the invention beyond those described herein. While the present invention has been described with reference to one or more particular embodiments, those skilled in the art recognize that many changes may be made thereto without departing from the scope of the present invention. It is therefore to be understood that within the scope of the appended claims and their equivalents, the invention may be practiced otherwise than as specifically described herein.

1. A semiconductor device, comprising:
a die layer comprising a main surface;
a plurality of first terminals mounted on the main surface of the die layer, the first terminals forming a grid of unit cells with hexagon contours arranged side-by-side across the main surface of the die layer;
a plurality of second terminals mounted on the main surface of the die layer, each second terminal forming a hexagon contour arranged within a unit cell of a respective first terminal, a gap being provided between the second terminal and the first terminal;
a plurality of third terminals mounted on the main surface of the die layer, each third terminal being formed as a hexagon contour and arranged within the hexagon contour of a respective second terminal, there being a second gap provided between the third terminal and the second terminal; and
at least two metallization layers arranged over the plurality of first, second and third terminals, the at least two metallization layers being configured to receive electrical currents from the plurality of first, second and third terminals.

2. The semiconductor device of claim 1, the first metallization layer comprising a first portion, a second portion and a third portion each separated from one another and arranged as follows:
the first portion of the first metallization layer covering at least a portion of each first terminal and electrically connected to the plurality of first terminals to receive electrical currents from the plurality of first terminals;
the second portion of the first metallization layer covering at least a portion of each second terminal and electrically connected to the plurality of second terminals to receive electrical currents from the plurality of second terminals; and
the third portion of the first metallization layer covering at least a portion of each third terminal and electrically connected to the plurality of third terminals to receive electrical currents from the plurality of third terminals.

3. The semiconductor device of claim 2, further comprising a second metallization layer positioned over the first metallization layer, the second metallization layer comprising a first portion, a second portion and a third portion separated from one another and arranged as follows:
the first portion of the first metallization layer is connected to the first portion of the second metallization layer to route the extracted currents from the plurality of first terminals to another entity;
the second portion of the first metallization layer is connected to the second portion of the second metallization layer to route the extracted currents from the plurality of second terminals to another entity; and
the third portion of the first metallization layer is connected to the third portion of the second metallization layer to route the extracted currents from the plurality of third terminals to another entity.

4. The semiconductor device of claim 2, wherein:
the first portion of the second metallization layer is formed with a curvilinear contour covering at least a portion of the hexagon contours of the plurality of first terminals;
the second portion of the second metallization layer is formed with a curvilinear contour covering at least a portion of the hexagon contours of the plurality of second terminals; and
the third portion of the second metallization layer is formed with a curvilinear contour covering the hexagons of the plurality of third terminals.

5. The semiconductor device of claim 4, further comprising an isolation layer positioned between the first metallization layer and the second metallization layer, each of the connections between the first portion of the first metallization layer and the first portion of the second metallization layer, the second portion of the first metallization layer and the second portion of the second metallization layer, and the third portion of the first metallization layer and the third portion of the second metallization layer being formed by vias extending through the isolation layer.

6. The semiconductor device of claim 1, wherein:
the first metallization layer comprises a first portion and a second portion which are separated from each other;
the first portion of the first metallization layer covers at least a portion of the plurality of first terminals to receive electrical currents from the first terminals; and
the second portion of the first metallization layer covers at least a portion of the plurality of second terminals to receive electrical currents from the second terminals.

7. The semiconductor device of claim 6, wherein:
the second metallization layer is positioned over the first metallization layer, the second metallization layer comprising a first portion and a second portion which are separated from each other; and
the first portion of the second metallization layer covers at least a portion of the plurality of third terminals to receive electrical currents from the third terminals.

8. The semiconductor device of claim 7, wherein:
the first portion of the second metallization layer is configured to route currents from the third terminals to another entity;
the first portion of the first metallization layer is configured to route currents from first terminals to another entity; and
the second portion of the second metallization layer is connected to the second portion of the first metallization layer to route currents from the second terminals to another entity.

9. The semiconductor device of claim 8, further comprising:
an isolation layer positioned between the first metallization layer and the second metallization layer, the connection between the second portion of the second metallization layer and the second portion of the first metallization layer being formed by a via extending through the isolation layer.

10. The semiconductor device of claim 1, wherein:
a first metallization layer covers at least a portion of the first terminals to receive electrical currents from the first terminals and route the currents from the first terminals to another entity;
a second metallization layer covers at least a portion of the second terminals to receive electrical currents from the second terminals and route the currents from the second terminals to another entity; and
a third metallization layer covers at least a portion of the third terminals to receive electrical currents from the third terminals and route the currents from the third terminals to another entity.

11. The semiconductor device of claim 10, wherein the second metallization layer is arranged in overlying relation to the first metallization layer, and the third metallization layer is arranged in overlying relation to the second metallization layer.

12. The semiconductor device of claim 10, wherein the third metallization layer fully covers the main surface of the die layer.

13. The semiconductor device of claim 10, wherein:
the third terminals covered at least partially by the third metallization layer are drain terminals; and
the first terminals and the second terminals are source terminals or gate terminals, respectively.

14. The semiconductor device according to claim 1, wherein at least one of the hexagon contours of the plurality of first terminals, the hexagon contours of the plurality of second terminals or the hexagons of the plurality of third terminals have cut corners or rounded corners.

15. The semiconductor device of claim 1, wherein the semiconductor device comprises a lateral power semiconductor device comprising a GaN High Electron Mobility Transistor (HEMT) device.

16. The semiconductor device of claim 1, wherein the die layer comprises a GaN layer and an AlGaN layer above the GaN layer and the main surface is formed in overlying relation to the AlGaN layer.

17. The semiconductor device of claim 16, wherein:
the plurality of first terminals, the plurality of second terminals and the plurality of third terminals are formed on one level on top of the AlGaN layer; or
at least one of the plurality of first terminals, the plurality of second terminals and the plurality of third terminals extends into the AlGaN layer; or
at least one of the plurality of first terminals, the plurality of second terminals and the plurality of third terminals extends into the GaN layer.

18. The semiconductor device of claim 16, wherein the semiconductor device comprises a GaN HEMT comprising a gate in at least partially p-type GaN semiconductor to obtain an enhanced mode that provides a normally off device.

19. The semiconductor device of claim 16, wherein the GaN layer is built on heteroepitaxial bulk comprising at least one of GaN-on-SOI, GaN on Sapphire, GaN-on SiC, or the GaN layer is built on GaN-on-GaN material.

20. The semiconductor device of claim 16, wherein the plurality of second terminals comprises a pGaN gate formed as a planar layer or as a filling layer to inhibit regrowth of pGaN in a trench gate.
